(19) United States
(12) Patent Application Publication
(10) Pub. No.: US 2012/0262852 A1
(43) Pub. Date: Oct. 18, 2012

(54) ELECTRONIC DEVICE WITH TOUCH MOUDLE

(75) Inventor: CHAO-YUAN CHENG, Tu-Cheng (TW)

(73) Assignee: HON HAI PRECISION INDUSTRY CO., LTD., Tu-Cheng (TW)

(21) Appl. No.: 13/160,513

(22) Filed: Jun. 15, 2011

(30) Foreign Application Priority Data
Apr. 14, 2011 (CN) 201110093595.6

(51) Int. Cl. H05K 5/03

(52) U.S. Cl. 361/679.01

(57) ABSTRACT

An electronic device includes a front cover, a cushion member and a touch module. The front cover includes a hollow frame and a screen area configured in hollow portion of the frame. The cushion member has similar hollow shape as that of the frame of the front cover and adhered on the hollow frame. The touch module includes a touch sensor layer and a substrate. The touch sensor layer is coated on the substrate. The substrate is adhered onto the cushion member with the touch sensor layer facing the screen area of the front cover.

### BACKGROUND

1. Technical Field

The present disclosure generally relates to electronic devices, and more particularly to a cover of an electronic device having a touch module.

2. Description of Related Art

Generally, an electronic device comprises a cover and a touch module adhered on an inner surface of the cover. The touch module comprises a first glass layer, a second glass layer and an indium tin oxide (ITO) layer disposed between the first and second glass layers. The first glass layer is adhered on the inner surface via double face glue. However, the first glass layer overlaps on the cover to cause a redundancy layer upon the ITO layer, which make against small size of the electronic device. Furthermore, the touch module is directly adhered onto the cover without a cushion member, like rubber, to protect the ITO layer when the electronic device falls down.

Therefore, a need exists in the industry to overcome the described limitations and reduce the size of the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a cover of an electronic device of an exemplary embodiment of the disclosure.

FIG. 2 is an exploded schematic view of FIG. 1.

FIG. 3 is a cross-section view of the cover of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

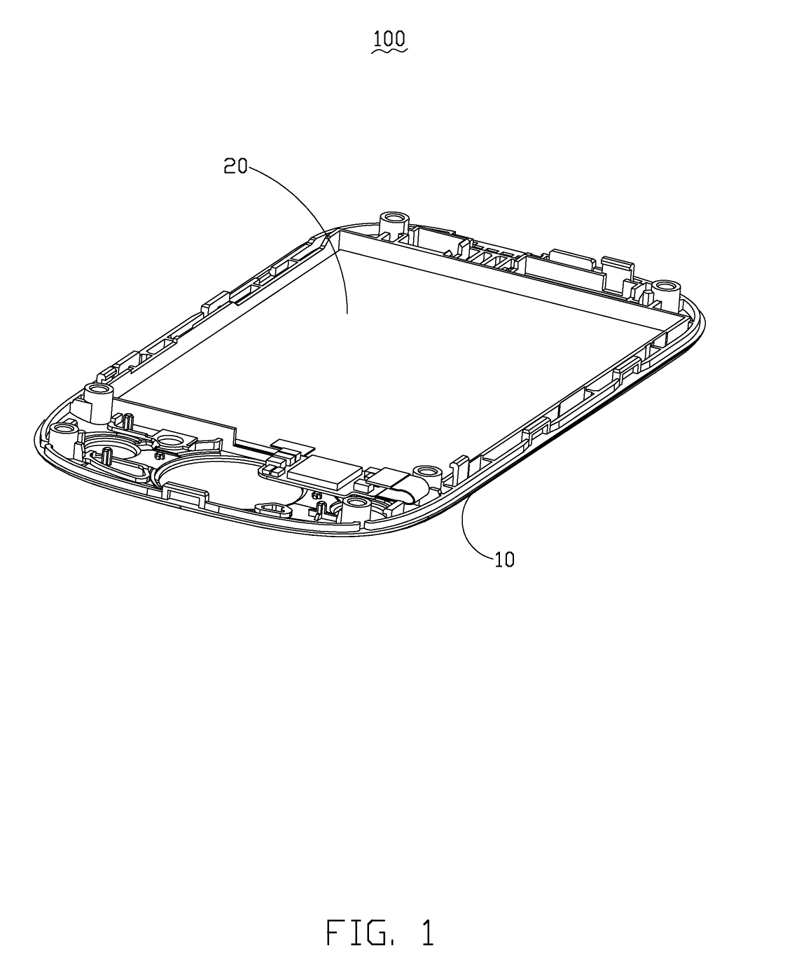

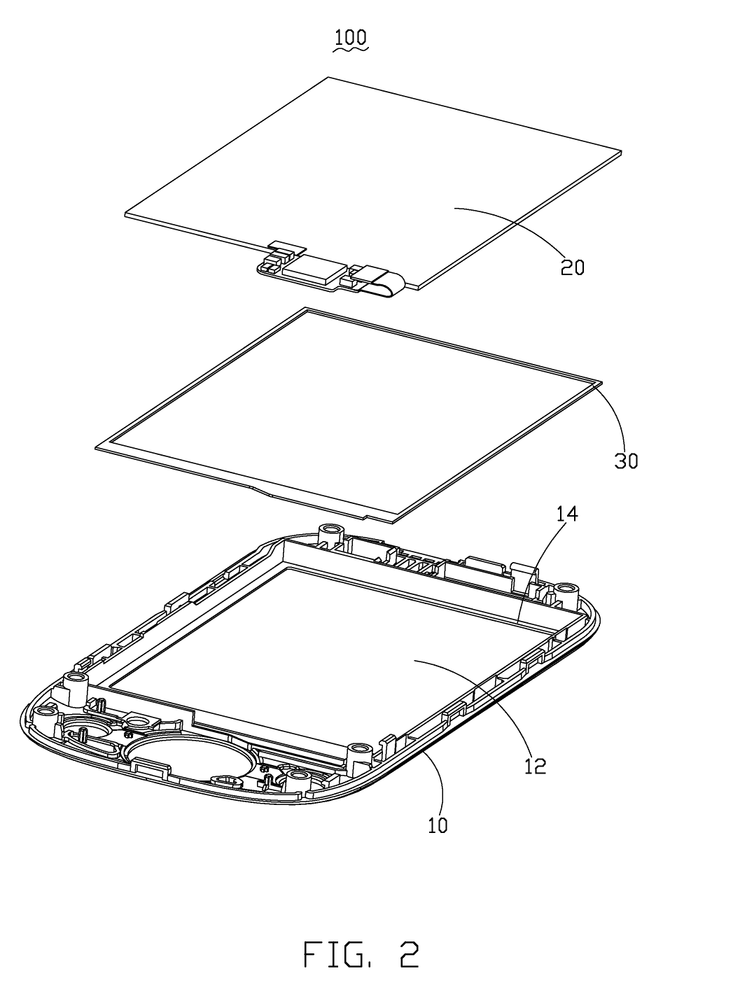

Referring to FIGS. 1-2, an electronic device 100 comprises a front cover 10, a cushion member 30 and a touch module 20. The touch module 20 is fixed onto the front cover 10 to form an integral structure with the cushion member 30 sandwiched between the front cover 10 and the touch module 20. Therefore, size of the electronic device 100 is made to be small due to the integral structure of the touch module 20 and the front cover 10. Furthermore, the touch module 20 is protected by the cushion member 30 when the electronic device 100 falls down.

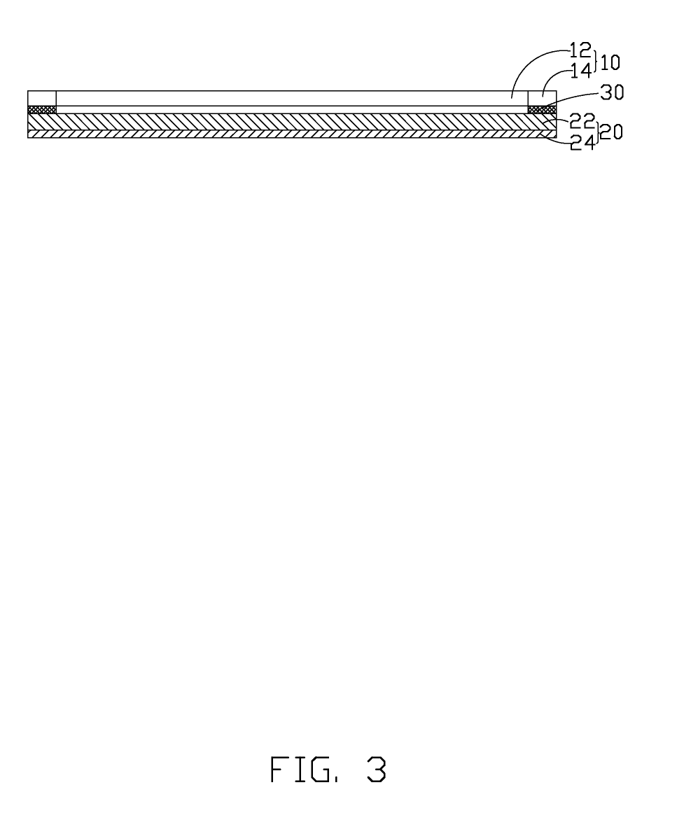

Referring to FIG. 3, the front cover 10 comprises a hollow frame 14 and a screen area 12 configured in hollow portion of the hollow frame 14. In this embodiment, the hollow frame 14 is integrated with the screen area 12, where the screen area 12 is transparent, and the hollow frame 14 is opaque. The hollow frame 14 secures the cushion member 30 and the touch module 20.

The cushion member 30 has a similar hollow shape as that of the frame 14 of the front cover 10 and is adhered on the hollow frame 14. In this embodiment, the cushion member 30 is formed from rubber or a gasket.

The touch module 20 comprises a touch sensor layer 22 and a substrate 24. The touch sensor layer 22 is coated on the substrate 24. The substrate 24 is adhered on the cushion member 30 with the touch sensor layer 22 facing the screen area 12 of the front cover 10. In this embodiment, the substrate 24 of the touch module 20 is formed from glass, and the touch sensor layer 22 is formed from indium tin oxide (ITO).

In summary, the cushion member 30 is sandwiched between and adhered to the front cover 10 and the touch module 20. The front cover 10 and the cushion member 30 both have hollow structures, and the touch module 30 comprises the touch sensor layer 22 facing to the hollow structures. Therefore, the touch module 20 is integrally fabricated with the front cover 10 with protection by the cushion member 30, so as to make smaller size of the electronic device 100.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. An electronic device, comprising:
a front cover, comprising a hollow frame and a screen area configured in hollow portion of the frame;
a cushion member, having a similar hollow shape as that of the hollow frame of the front cover and being adhered onto the hollow frame; and
a touch module, comprising a touch sensor layer and a substrate, wherein the touch sensor layer is coated on the substrate, the substrate is adhered on the cushion member with the touch sensor layer facing the screen area of the front cover.

2. The electronic device as claimed in claim 1, wherein the hollow frame is integrated with the screen area, the screen area is transparent, and the hollow frame is opaque.

3. The electronic device as claimed in claim 1, wherein the cushion member is formed from rubber.

4. The electronic device as claimed in claim 1, wherein the cushion member is formed from a gasket.

5. The electronic device as claimed in claim 1, wherein the substrate of the touch module is formed from glass.

6. The electronic device as claimed in claim 5, wherein the touch sensor layer is formed from indium tin oxide (ITO).

7. An electronic device, comprising a front cover, a touch module and a cushion member sandwiched between and adhered to the front cover and the touch module, wherein the front cover and the cushion member both have hollow structures and the touch module comprises a touch sensor layer facing to the hollow structures.

8. The electronic device as claimed in claim 7, wherein the hollow frame is integrally with the screen area, the screen area is transparent, and the hollow frame is opaque.

9. The electronic device as claimed in claim 7, wherein the cushion member is formed from rubber.

10. The electronic device as claimed in claim 7, wherein the cushion member is formed from a gasket.

11. The electronic device as claimed in claim 7, wherein the touch module comprises a substrate formed from glass, on which the touch layer coated.

12. The electronic device as claimed in claim 11, wherein the touch sensor layer is formed from indium tin oxide (ITO).
